(19) United States
(12) Patent Application Publication
(10) Pub. No.: US 2010/0282599 A1
(43) Pub. Date: Nov. 11, 2010

(54) Method for manufacturing of hydrogen generating apparatus and hydrogen generating apparatus using the same

(75) Inventors: Jae-Hyuk Jang, Seongnam-si (KR); Jae-Hyoung Gil, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,791

(22) Filed: Apr. 4, 2008

(30) Foreign Application Priority Data
Sep. 21, 2007 (KR) 10-2007-0096712

(51) Int. Cl. C25B 9/00; H05K 13/00

(52) U.S. Cl. 204/242; 29/592.1

(57) ABSTRACT

A method of manufacturing a hydrogen generating apparatus and a hydrogen generating apparatus manufactured using this method are disclosed. The method includes: inserting an elastic member inside a reactor, which has one side open; inserting an electrode, to which a wire is connected, and an aqueous electrolyte solution inside the elastic member; placing a cover, in which a through-hole is formed, on the open side of the reactor, such that a portion of the wire is positioned outside the reactor; and connecting the portion of the wire positioned outside the reactor to a control unit. Using this method, the inner materials remaining inside the reactor can be removed in a simple manner after the reaction, and replacement costs can be saved as the reactor itself does not have to be replaced.

### CROSS-REFERENCE TO RELATED APPLICATIONS

This application claims the benefit of Korean Patent Application No. 10-2007-0096712 filed with the Korean Intellectual Property Office on Sep. 21, 2007, the disclosure of which is incorporated herein by reference in its entirety.

### BACKGROUND

1. Technical Field

The present invention relates to a method of manufacturing a hydrogen generating apparatus and to a hydrogen generating apparatus using the same.

2. Description of the Related Art

A fuel cell is an apparatus that converts the chemical energies of fuel (hydrogen, LNG, LPG, methanol, etc.) and air directly into electricity and heat, by means of electrochemical reactions. In contrast to conventional power generation techniques, which employ the processes of burning fuel, generating vapor, driving turbines, and driving power generators, the utilization of fuel cells does not entail combustion processes or driving apparatus. As such, the fuel cell is a relatively new technology for generating power, which offers high efficiency and few environmental problems.

FIG. 1 is a diagram illustrating the operational principle of a typical fuel cell.

Referring to FIG. 1, a fuel cell 100 may include a fuel electrode 110 as an anode and an air electrode 130 as a cathode. The fuel electrode 110 receives molecular hydrogen (H₂), which is dissociated into hydrogen ions (H⁺) and electrons (e⁻). The hydrogen ions move past a membrane 120 towards the air electrode 130. This membrane 120 corresponds to an electrolyte layer. The electrons move through an external circuit 140 to generate an electric current. The hydrogen ions and the electrons combine with the oxygen in the air at the air electrode 130 to generate water. The following Reaction Scheme 1 represents the chemical reactions described above.

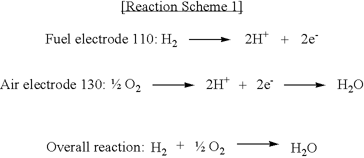

In short, the fuel cell can function as a battery, as the electrons dissociated from the fuel electrode 110 generate a current that passes through the external circuit. Such a fuel cell 100 is a pollution-free power source, because it does not produce any polluting emissions such as SOx, NOx, etc., and produces only little amounts of carbon dioxide. Also, the fuel cell may offer several other advantages, such as low noise and little vibration, etc.

One of the most crucial tasks required for the fuel cell is the stable supply of hydrogen. A hydrogen storage tank can be used for this purpose, but the tank apparatus occupies a large volume and has to be kept with special care.

In order for the fuel cell to suitably accommodate the demands in current portable electronic equipment (cell phones, laptops, etc.) for high-capacity power supply apparatus, the fuel cell needs to provide a small volume and high performance.

Thus, a reasonable alternative can be to produce hydrogen using a hydrogen generating apparatus. The hydrogen generating apparatus may convert a regular fuel containing hydrogen atoms into gases containing a large quantity of hydrogen gas, which can then be used by the fuel cell 100.

The fuel cell may employ a method of generating hydrogen after reforming fuel, such as methanol or formic acid, etc., approved by the ICAO (International Civil Aviation Organization) for boarding on airplanes, or may employ a method of using methanol, ethanol, or formic acid, etc., directly as the fuel.

However, the former case may require a high reforming temperature, a complicated system, and high driving power, and is likely to have impurities (e.g. CO₂, CO, etc.) included, besides pure hydrogen. On the other hand, the latter may entail the problem of very low power density, due to the low rate of a chemical reaction at the anode and the cross-over of hydrocarbons through the membrane.

In comparison, by using a hydrogen generating apparatus that utilizes electrochemical reactions, pure hydrogen can be obtained at room temperature. Also, a simple system can be implemented using only a cartridge and stack, and it is possible to obtain a desired flow rate of hydrogen without a separate BOP unit, by regulating the electric current to control the amount of hydrogen produced.

In the conventional hydrogen generating apparatus, after a reaction is completed, the reactor may need to be replaced in order to start a new reaction. That is, since the reaction does not continue after the magnesium electrode is completely expended, the reactor has to be replaced in order to proceed with a new reaction.

In the case of a highly miniaturized reactor, the cost for replacing the reactor may not pose such a large problem, as the reactor has a small volume and may be inexpensive to fabricate. However, in a portable power supply apparatus in the level of several tens to several hundreds of watts, the volume of the reactor itself may range from several hundreds of milliliters to several tens of liters, and the cost of replacing such a reactor may act as a large burden.

Furthermore, the side product of Mg(OH)₂ may remain, and as the magnesium (Mg) electrode, the stainless steel electrode, and the electrolyte may not be completely expended, the problem may be added of having to dispose of these materials.

### SUMMARY

An aspect of the invention is to provide a method of manufacturing a hydrogen generating apparatus and a hydrogen generating apparatus manufactured using this method, with which inner materials remaining inside the reactor after the reaction can be removed in a simple manner, and in which the reaction area between the electrodes and the electrolyte solution can be increased.

One aspect of the invention provides a method of manufacturing a hydrogen generating apparatus. This method includes: inserting an elastic member inside a reactor, which has one side open; inserting electrodes, to which wires are connected, and an aqueous electrolyte solution inside the elastic member; placing a cover, in which at least one through-hole is formed, on the open side of the reactor, such that portions of the wires are positioned outside the reactor; and connecting the portions of the wires positioned outside the reactor to a control unit.

The elastic member can be made of any one of rubber and vinyl.

The operation of placing the cover can include: inserting a rubber ring in a groove formed along a rim of the open portion of the reactor, and forming a seal between the cover and the reactor with the rubber ring interposed between the cover and the reactor.

Also, a sealant can be filled in the through-hole to isolate the inside and outside of the reactor.

Before inserting the elastic member, the method may further include forming at least one mounting indentation inside the reactor such that secures at least one of the electrodes.

Another aspect of the invention provides a hydrogen generating apparatus, which includes: a reactor, of which one side is open; a cover, which covers the open side of the reactor, and in which at least one through-hole is formed; an elastic member, which is inserted inside the reactor and secured to the cover, and which holds an aqueous electrolyte solution; and an electrode, which is held inside the elastic member, and to which is connected a wire that penetrates through the through-hole.

Here, the hydrogen generating apparatus may further include a rubber ring, which is inserted in a hole formed along a rim of the open portion of the reactor, and which is coupled with the cover and the reactor, thereby forming a seal between the cover and the reactor.

Also, a sealant may further be included, which is filled in the through-hole to isolate the inside and outside of the reactor.

At least one mounting indentation can be formed inside the reactor, in which the electrode may be mounted, and the elastic member can be made of any one of rubber and vinyl.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a diagram illustrating the operational principle of a fuel cell.

FIG. 2 is a schematic diagram illustrating a hydrogen generating apparatus.

FIG. 3 is a flowchart illustrating a method of manufacturing a hydrogen generating apparatus according to an embodiment of the invention.

FIG. 4, FIG. 5, FIG. 6, and FIG. 7 are cross-sectional views illustrating a method of manufacturing a hydrogen generating apparatus according to an embodiment of the invention.

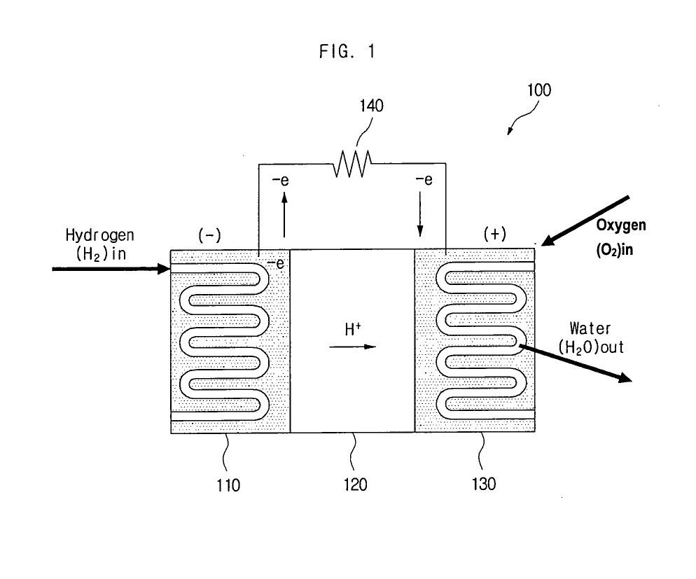

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Certain embodiments of the invention will now be described below in more detail with reference to the accompanying drawings.

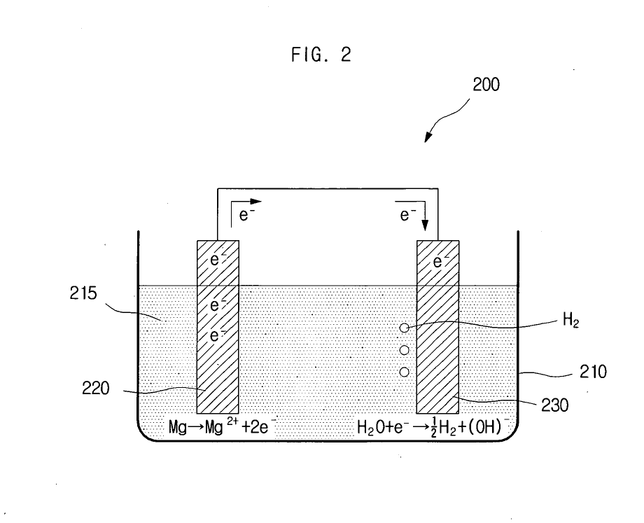

Methods used in generating hydrogen for a proton exchange membrane fuel cell (PEMFC) can be divided mainly into methods utilizing the oxidation of aluminum, methods utilizing the hydrolysis of metal borohydrides, and methods utilizing reactions on metal electrodes. Among these, one method of efficiently regulating the rate of hydrogen generation is the method of using metal electrodes. FIG. 2 is a schematic diagram illustrating a hydrogen generating apparatus that uses metal electrodes.

In the illustrated drawing, an anode 220 made of magnesium and a cathode 230 made of stainless steel are dipped in an aqueous electrolyte solution 215 inside an electrolyte bath 210.

The basic principle of the hydrogen generating apparatus 200 is that electrons are generated at the magnesium electrode 220, which has a greater tendency to ionize than the stainless steel electrode 230, and the generated electrons travel to the stainless steel 230 electrode. The electrons can then react with the aqueous electrolyte solution 215 to generate hydrogen.

The following Reaction Scheme 2 represents the chemical reactions in the hydrogen generating apparatus 200 described above.

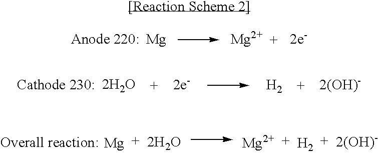

This is a method in which the electrons obtained when magnesium in the electrode 220 is ionized to Mg²⁺ ions are moved through a wire and connected to another metal object (e.g. aluminum or stainless steel), where hydrogen is generated by the dissociation of water. The amount of hydrogen generated can be regulated on demand, as it is related to the distance between electrodes and the sizes of the electrodes.

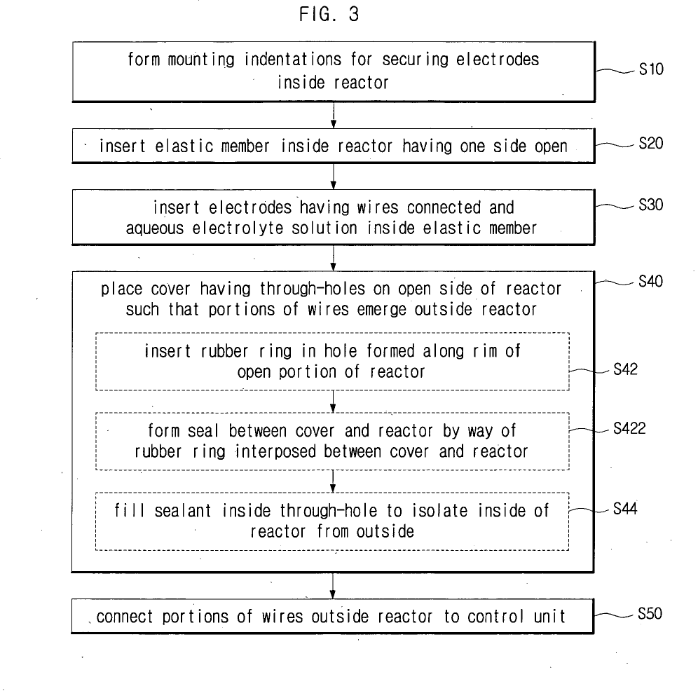

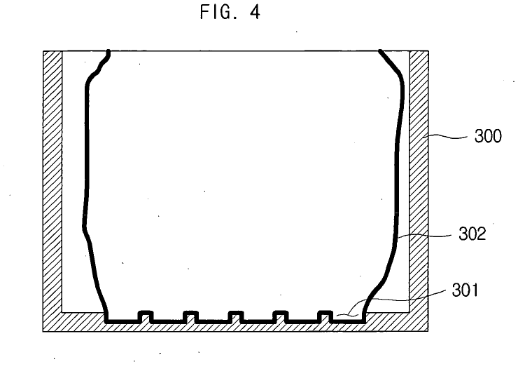

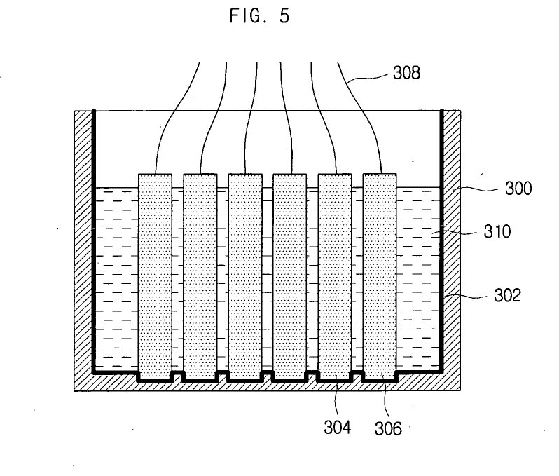

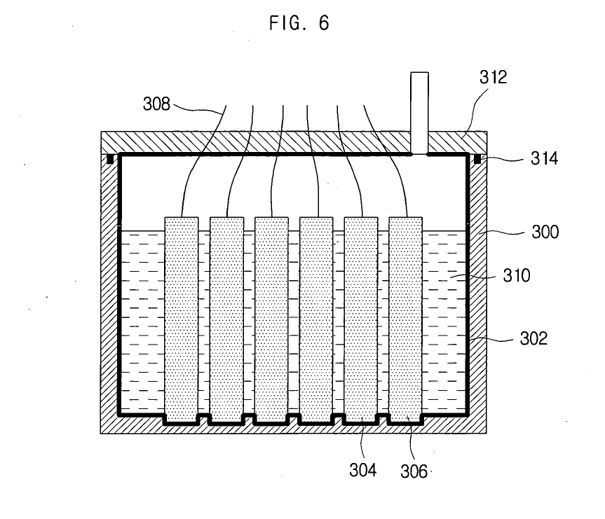

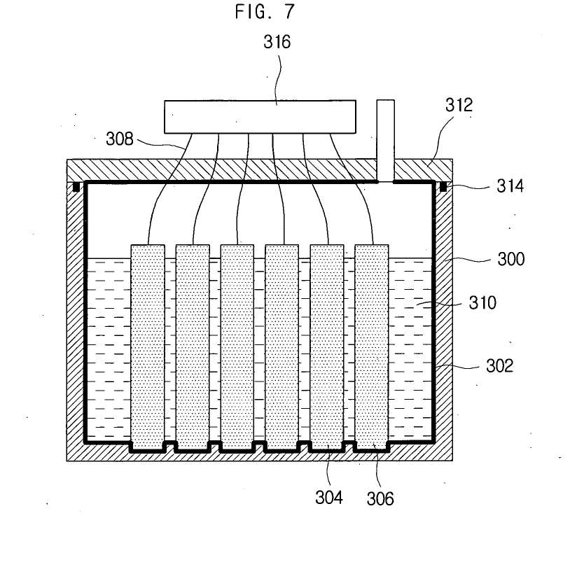

FIG. 3 is a flowchart illustrating a method of manufacturing a hydrogen generating apparatus according to an embodiment of the invention, and FIG. 4 to FIG. 7 are cross-sectional views illustrating a method of manufacturing a hydrogen generating apparatus according to an embodiment of the invention. In FIGS. 4 to 7 are illustrated a reactor 300, mounting indentations 301, an elastic member 302, first electrodes 304, second electrodes 306, wires 308, an aqueous electrolyte solution 310, a cover 312, a rubber ring 314, and a control unit 316.

With this embodiment of the invention, after a reaction is finished in the hydrogen generating apparatus, the impurities and inner materials remaining within the reactor can be removed in a simple manner, and as the reactor does not have to be replaced, the replacement cost for the reactor can be saved.

For better understanding and easier explanation, the following description will focus on an arrangement in which the first electrode 304 is made of magnesium (Mg) and the second electrode 306 is made of stainless steel.

First, mounting indentations 301 may be formed inside the reactor 300 which secure the electrodes 304, 306 (S10). The mounting indentations 301 illustrate just one example of a way to secure the electrodes 304, 306, and it is obvious that various other methods may be used for securing the electrodes 304, 306.

Next, as illustrated in FIG. 4, the elastic member 302 may be inserted inside the reactor 300, which has one side open (S20). The electrodes 304, 306, which will be described in more detail later, may be inserted inside the reactor 300, and the aqueous electrolyte solution 310 may be held in the reactor 300 as well. Before the electrodes 304, 306 and the aqueous electrolyte solution 310 are placed inside the reactor 300, the elastic member 302, which can be made of a rubber or vinyl material, may be inserted inside the reactor 300.

Due to the elasticity of the elastic member 302, the elastic member 302 may expand to the form of the reactor 300 when the electrodes 304, 306 or aqueous electrolyte solution 310 are inserted. This can be seen in FIG. 5. As illustrated in FIG. 5, the electrodes 304, 306, to which the wires 308 are connected, and the aqueous electrolyte solution 310 may be inserted inside the elastic member 302 (S30).

Here, with the inner materials inserted inside the elastic member 302, and as with the progression of the reactions, the fuel will be expended, and the amount of inner materials may be decreased. As the amount of inner materials decrease, however, the elastic member 302 holding the inner materials may contract as well. Thus, according to the contraction of the elastic member 302, the level of the aqueous electrolyte solution 310 held inside the elastic member 302 may be raised, whereby the reaction areas between the electrodes 304, 306 and the aqueous electrolyte solution 310 may be increased, so that consequently the efficiency of hydrogen generation can be increased.

The electrodes 304, 306 may be secured within the reactor 300, where the present embodiment illustrates the case of securing the electrodes 304, 306 inside the reactor 300 by way of the mounting indentations 301 formed in the reactor 300. Of course, any of various other methods known to those skilled in the art may be used for securing the electrodes 304, 306 in the reactor 300.

The aqueous electrolyte solution 310 may contain hydrogen ions, which can be used by the hydrogen generating, apparatus to generate hydrogen gas. A compound such as LiCl, KCl, NaCl, KNO₃, NaNO₃, CaCl₂, MgCl₂, K₂SO₄, Na₂SO₄, MgSO₄, AgCl, etc., can be used in the aqueous electrolyte solution 310 as the electrolyte.

The first electrode 304 and second electrode 306 may be secured in the reactor 300 for the reactions, an example of which is illustrated in the drawings.

The first electrode 304 may be an active electrode, where the magnesium (Mg) is oxidized into a magnesium ion (Mg²⁺) releasing two electrons, due to the difference in ionization energy between magnesium and water (H₂O).

On the other hand, the second electrode 306 may be an inactive electrode and may not be expended, unlike the first electrode 304. Thus, the second electrode 306 may be formed to a lower thickness than that of the first electrode 304. The second electrode 306 may receive the electrons that have traveled from the magnesium of the first metal electrode 304 and may react with the aqueous electrolyte solution 310 to generate hydrogen.

Next, as illustrated in FIG. 6, the cover 312, in which through-holes are formed, may be placed on the open side of the reactor 300 such that portions of the wires 308 are outside the reactor 300 (S40). The elastic member 302 inside the reactor 300 can elastically expand according to the quantity of the electrolyte solution 310. Also, when the cover 312 is placed on the reactor 300, the elastic member 302 can be secured to an inner surface of the cover 312 forming the inside of the reactor 300.

Here, the cover 312 and the reactor 300 can be configured to couple together simply by pressing. This will allow the reactor 300 and cover 312 to be coupled and separated easily.

Also, when the cover 312 and reactor 300 are coupled together, a rubber ring 314 may be used in coupling the cover 312 with the reactor 300. That is, a rubber ring 314 may be inserted in a hole formed along the rim of the open portion of the reactor 300 (S42), and a seal may be formed between the cover 312 and reactor 300 by way of the rubber ring 314 interposed between the cover 312 and the reactor 300 (S422). In this way, the reactor 300 and cover 312 can be firmly secured.

Also, when placing the cover 312 on the reactor 300, through-holes may be formed in the cover 312 so that the wires 308 may emerge outside the cover 312, while a sealant may be applied in the through-holes through which the wires 308 pass to isolate the inside of the reactor 300 from the outside (S44). By sealing the through-holes through which the wires 308 pass, the hydrogen generated in the reactor 300 can be prevented from leaking out.

The material for the sealant may be the same as the material used for the elastic member 302, i.e. rubber or vinyl, or may be another type of adhesive material capable of filling the through-holes.

Next, as illustrated in FIG. 7, the portions of the wires 308 outside the reactor 300 may be connected with a control unit 316 (S50). Utilizing the control unit 316, the amount of hydrogen generated can be regulated.

As described above, an elastic member 302 may be inserted in the reactor 300, and the inner materials may be formed inside the elastic member 302, including electrodes 304, 306, to which wires 308 are connected, and an aqueous electrolyte solution 310. A method of removing the elastic member 302 and the inner materials from the reactor 300 is as follows.

First, the wires 308 connected with the control unit 316 may be cut, after which the cover 312 may be opened from the reactor 300, and the securing portion between the elastic member 302 and the cover 312 may be removed, and then the elastic member 302 containing the electrodes 304, 306 to which the wires 308 are connected and the aqueous electrolyte solution 310 may be removed. In this way, the side products of the reaction, the electrodes remaining after their expenditure, and the electrolyte solution can all be removed simultaneously.

FIG. 7 is a cross-sectional view of a hydrogen generating apparatus according to an embodiment of the invention. In FIG. 7 are illustrated a reactor 300, mounting indentations 301, an elastic member 302, first electrodes 304, second electrodes 306, wires 308, an aqueous electrolyte solution 310, a cover 312, a rubber ring 314, and a control unit 316.

The reactor 300 holds the elastic member 302 inside.

The elastic member 302 may be inserted inside the reactor 300 and may include in its inside the electrodes, including first electrodes 304 and second electrodes 306, and the aqueous electrolyte solution 310. The elastic member 302 can be made of rubber or vinyl, and when the aqueous electrolyte solution 310 is placed inside the elastic member 302, the elastic member 302 may change its shape to fit the form of the reactor 300.

The elastic member 302 formed inside the reactor 300 may elastically expand according to the amount of aqueous electrolyte solution 310. Also, when the cover 312 is placed on the reactor 300, the elastic member 302 may be secured to an inner surface of the cover 312 formed inside the reactor 300.

After the inner materials are inserted inside the elastic member 302, progression of the reaction may cause the fuel to be expended and the amount of inner materials to be reduced. As the amount of inner materials decrease, the elastic member 302 containing the inner materials may contract accordingly. Thus, due to the contraction of the elastic member 302, the level of the aqueous electrolyte solution 310 held in the elastic member 302 may be raised, whereby the reaction areas between the electrodes 304, 306 and the aqueous electrolyte solution 310 may be increased, and consequently the efficiency of hydrogen generation can be increased.

The electrodes 304, 306 can be grouped into first electrodes 304 and second electrodes 306, which may be connected to the wires 308 that serve as passages for the movement of electrons.

The aqueous electrolyte solution 310 may contain hydrogen ions, which can be used by the hydrogen generating apparatus to generate hydrogen gas. A compound such as LiCl, KCl, NaCl, KNO₃, NaNO₃, CaCl₂, MgCl₂, K₂SO₄, Na₂SO₄, MgSO₄, AgCl, etc., can be used in the aqueous electrolyte solution 310 as the electrolyte.

The first electrode 304 may be formed on one side within the reactor 300 and may generate electrons. The first electrode 304 may be an active electrode, where the magnesium (Mg) is oxidized into a magnesium ion (Mg²⁺) releasing two electrons, due to the difference in ionization energy between magnesium and water (H₂O).

The electrons thus generated may travel through the wire 308 to the control unit 316, and through the wire 308 to the second electrode 306. As such, the first electrode 304 may be expended in accordance with the electrons generated, and may have to be replaced after a certain period of time. Also, the first electrode 304 may be made of a metal having a greater tendency to ionize than the material used for the second electrode 306.

The second electrode 306 may be formed adjacent to the first electrode 304, and may generate hydrogen using the electrons and the aqueous electrolyte solution 310. The second electrode 306 may be an inactive electrode. The second electrode 306 may receive the electrons that have traveled from the magnesium of the first metal electrode 304 and may react with the aqueous electrolyte solution 310 to generate hydrogen.

Also, as the second electrode 306 may be an inactive electrode and may not be expended, unlike the first electrode 304, the second electrode 306 may be formed to a lower thickness than that of the first electrode 304.

To be more specific, the chemical reaction at the second electrode 306 involves water being dissociated at the second electrode 306 after receiving the electrons from the first electrode 304.

The reaction above can be represented by the following Reaction Scheme 3.

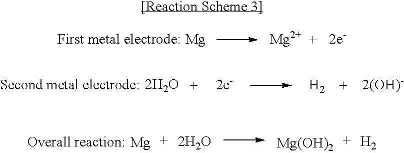

The rate and efficiency of the chemical reactions described above are determined by a number of factors. Examples of factors that determine the reaction rate include the area of the first electrode 304 and/or the second electrode 306, the concentration of the aqueous electrolyte solution 310, the type of aqueous electrolyte solution 310, the number of first electrodes 304 and/or second electrodes 306, the method of connection between the first electrode 304 and the second electrode 306, and the electrical resistance between the first electrode 304 and the second electrode 306.

Changes in the factors described above can alter the amount of electric current flowing between the first electrode 304 and second electrode 306, whereby the rate of the electrochemical reactions represented in Reaction Scheme 3 may be changed. A change in the rate of the electrochemical reactions will result in a change in the amount of hydrogen generated at the second electrode 306.

Thus, in embodiments of the invention, it is possible to regulate the amount of hydrogen generated by regulating the amount of electric current flowing between the first electrode 304 and the second electrode 306. The underlying principle of this can be explained by the following Equation 1 using Faraday's law.

$${N}_{hydrogen} = \frac{i}{n E} \\ {N}_{hydrogen} = \frac{i}{2 \times 96485} ( mol ) \\ \begin{matrix}{V}_{hydrogen} = \frac{i}{2 \times 96485} \times 60 \times 22400 ( ml \text{/} min ) \\ = 7 \times i ( ml \text{/} min )\end{matrix} \qquad [ Equation 1 ]$$

Here, N_{hydrogen} represents the amount of hydrogen generated per second (mol/sec), and V_{hydrogen} represents the volume of hydrogen generated per minute (ml/min). i represents current (C/s), n represents the number of reacting electrons, and E represents the charge per one mole of electrons (C/mol).

With reference to Reaction Scheme 3 described above, as two electrons react at the second electrode 306, n equals 2, and the charge per one mole of electrons is about −96,485 coulombs.

The volume of hydrogen generated in one minute can be calculated by multiplying the amount of hydrogen generated in one second by the time (60 seconds) and the volume of one mole of hydrogen (22,400 ml).

If the fuel cell is used in a 2 W system, the required amount of hydrogen may be about 42 ml/mol, and 6 A of electric current may be needed. If the fuel cell is used in a 5 W system, the required amount of hydrogen may be about 105 ml/mol, and 15 A of electric current may be needed.

Accordingly, by regulating the amount of electric current flowing between the first electrode 304 and the second electrode 306, the hydrogen generating apparatus can be made to generate the amount of hydrogen required by the connected fuel cell.

In embodiments of the invention, the first electrode 304 can be made of a metal other than magnesium that has a relatively high ionization tendency, such as iron (Fe) or an alkali metal such as aluminum (Al), zinc (Zn), etc. The second electrode 306 can be made of a metal such as platinum (Pt), copper (Cu), gold (Au), silver (Ag), iron (Fe), etc., that has a relatively lower ionization tendency than that of the metal used for the first electrode 304.

The control unit 316 may regulate the rate by which the electrons generated at the first electrode 304 by the electrochemical reactions are transferred to the second electrode 306, that is, the control unit 316 may regulate the electric current.

The control unit 316 may be inputted with the amount of power or amount of hydrogen required by the fuel cell, and if the required value is high, may increase the amount of electrons flowing from the first electrode 304 to the second electrode 306, or if the required value is low, may decrease the amount of electrons flowing from the first electrode 304 to the second electrode 306.

For example, the control unit 316 may include a variable resistance, to regulate the electric current flowing between the first electrode 304 and second electrode 306 by varying the resistance value, or may include an on/off switch, to regulate the electric current flowing between the first electrode 304 and second electrode 306 by controlling the on/off timing.

The cover 312 may be coupled with the reactor 300 such that the wires 308 emerge outside the reactor 300. To let portions of the wires 308 emerge out of the reactor 300, through-holes may be formed in the cover 312 through which the wires 308 may pass. Here, in order to prevent the hydrogen generated in the reactor 300 from leaking out, a sealant may be applied in the through-holes. Thus, the inside and outside of the reactor can be isolated.

The cover 312 and the reactor 300 can be configured to couple together simply by pressing, so that the reactor 300 and cover 312 can be coupled and separated easily.

Also, when the cover 312 and reactor 300 are coupled together, a rubber ring 314 may be inserted in a hole formed along the rim of the open portion of the reactor 300, and a seal may be formed between the cover 312 and reactor 300 by way of the rubber ring 314 interposed between the cover 312 and the reactor 300. In this way, the coupling between the reactor 300 and cover 312 can be firmly secured, and the hydrogen generated in the reactor 300 can be prevented from leaking out.

Of course, a fuel cell power generation system, which includes a fuel cell that receives the hydrogen supplied by the hydrogen generating apparatus described above and converts the chemical energy of the hydrogen to electrical energy to produce a direct current, is encompassed within the scope of this invention.

A method of manufacturing a hydrogen generating apparatus and a hydrogen generating apparatus manufactured using this method, according to certain aspects of the invention as set forth above, makes it possible to remove in a simple manner the inner materials remaining inside the reactor after the reaction, and to save on replacement costs as the reactor itself does not have to be replaced. Also, due to the contraction of the elastic member, according to reductions in the amount of inner materials during the course of the reaction, the level of the electrolyte solution can be raised, whereby the reaction area between the electrodes and the electrolyte solution can be increased.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a hydrogen generating apparatus, the method comprising:
inserting an elastic member inside a reactor, the reactor having one side thereof open;
inserting electrodes and an aqueous electrolyte solution inside the elastic member, the electrodes having wires connected thereto;
placing a cover having at least one through-hole formed therein on the open side of the reactor such that portions of the wires are positioned outside the reactor; and
connecting the portions of the wires positioned outside the reactor to a control unit.

2. The method of claim 1, wherein the elastic member is made of any one of rubber and vinyl.

3. The method of claim 1, wherein placing the cover comprises:
inserting a rubber ring in a groove formed along a rim of the open portion of the reactor; and
forming a seal between the cover and the reactor by way of the rubber ring interposed between the cover and the reactor.

4. The method of claim 1, further comprising:
filling a sealant in the through-hole to isolate an inside from an outside of the reactor.

5. The method of claim 1, further comprising, before inserting the elastic member:
forming at least one mounting indentation inside the reactor such that secures at least one of the electrodes.

6. A hydrogen generating apparatus comprising:
a reactor having one side thereof open;
a cover covering the open side of the reactor and having at least one through-hole formed therein;
an elastic member inserted inside the reactor to be secured to the cover and holding an aqueous electrolyte solution; and
an electrode held inside the elastic member and having a wire connected thereto, the wire penetrating the through-hole.

7. The hydrogen generating apparatus of claim 6, further comprising:
a rubber ring inserted in a hole formed along a rim of the open portion of the reactor and coupled with the cover and the reactor to form a seal between the cover and the reactor.

8. The hydrogen generating apparatus of claim 6, further comprising:
a sealant filled in the through-hole to isolate an inside from an outside of the reactor.

9. The hydrogen generating apparatus of claim 6, wherein at least one mounting indentation is formed inside the reactor, and the electrode is mounted in the mounting indentation.

10. The hydrogen generating apparatus of claim 6, wherein the elastic member is made of any one of rubber and vinyl.
